(19) United States
(12) Patent Application Publication
(10) Pub. No.: US 2022/0052113 A1
(43) Pub. Date: Feb. 17, 2022

(54) SEMICONDUCTOR DEVICE INCLUDING DATA STORAGE MATERIAL PATTERN AND SELECTOR MATERIAL PATTERN

(71) Applicant: Samsung Electronics Co., Ltd., Suwon-si (KR)

(72) Inventors: Jabin LEE, Hwaseong-si (KR); Zhe WU, Seoul (KR); Chungman KIM, Suwon-si (KR); Kwangmin PARK, Seoul (KR); Dongho AHN, Hwaseong-si (KR); Seunggeun YU, Seoul (KR); Jinwoo LEE, Seoul (KR); Soyeon CHOI, Gangjin-gun (KR)

(73) Assignee: Samsung Electronics Co., Ltd., Suwon-si (KR)

(21) Appl. No.: 17/220,998

(22) Filed: Apr. 2, 2021

(30) Foreign Application Priority Data
Aug. 14, 2020 (KR) 10-2020-0102222

(51) Int. Cl. H01L 27/24; H01L 45/00

(52) U.S. Cl. CPC H01L 27/2427; H01L 45/1675; H01L 45/06; H01L 27/2481

(57) ABSTRACT

A semiconductor device includes a lower insulating structure covering a circuit element on a semiconductor substrate and an upper structure on the lower insulating structure. The upper structure includes a memory cell structure between first and second conductive lines. The first conductive lines extend in a first horizontal direction, and the second conductive lines extend in a second horizontal direction. The memory cell structure includes at least three electrode patterns, a data storage material pattern, and a selector material pattern overlapping in a vertical direction. The selector material pattern includes a threshold switching material and a metal material. The threshold switching material includes germanium (Ge), arsenic (As), and selenium (Se), and the metal material includes at least one of tungsten (W), titanium (Ti), aluminum (Al), and copper (Cu). A content of the metal material is greater than 0 atomic % and less than 2 atomic %.

### CROSS-REFERENCE TO RELATED APPLICATION(S)

This application claims benefit of priority to Korean Patent Application No. 10-2020-0102222 filed on Aug. 14, 2020 in the Korean Intellectual Property Office, the disclosure of which is incorporated herein by reference in its entirety.

### BACKGROUND

The present disclosure relates to semiconductor devices, and more particularly, to a semiconductor device including a data storage material pattern and a selector material pattern.

With the trend for high performance and low power consumption in semiconductor devices such as memory devices, next-generation memory devices such as PRAM, RRAM, and the like, have been developed. Such next-generation memory devices may have resistance values varying depending on current or voltage and may maintain resistance values thereof even when current or voltage supplies thereof are interrupted.

### SUMMARY

Example embodiments provide a semiconductor device including a data storage material pattern and a selector material pattern.

According to an example embodiment, a semiconductor device includes a semiconductor substrate, a circuit element on the semiconductor substrate, a lower insulating structure covering the circuit element, circuit interconnections in the lower insulating structure on the circuit interconnections being electrically connected to the circuit element, and an upper structure on the lower insulating structure. The upper structure includes first conductive lines, second conductive lines, and a memory cell structure between the first conductive lines and the second conductive lines. The first conductive lines extend in a first horizontal direction. The second conductive lines extend in a second horizontal direction, perpendicular to the first horizontal direction. The memory cell structure includes at least three electrode patterns, a data storage material pattern, and a selector material pattern overlapping each other in a vertical direction. The selector material pattern includes a threshold switching material and a metal material. The threshold switching material includes germanium (Ge), arsenic (As), and selenium (Se), and the metal material includes at least one of tungsten (W), titanium (Ti), aluminum (Al), and copper (Cu). A content of the metal material in the selector material pattern is greater than 0 atomic % and less than 2 atomic %.

According to an example embodiment, a semiconductor device includes a semiconductor substrate, first conductive lines extending in a first horizontal direction on the semiconductor substrate, a memory cell structure on the first conductive lines, and second conductive lines on the memory cell structure and extending in a second horizontal direction perpendicular to the first horizontal direction. The memory cell structure includes a first electrode pattern on the first conductive lines, a second electrode pattern on the first electrode pattern, and a data storage material pattern and a selector material pattern between the first electrode pattern and the second electrode pattern. The selector material pattern includes a threshold switching material including germanium (Ge), arsenic (As), and selenium (Se). The selector material pattern includes a metal material in common with the first conductive lines or the second conductive lines. The metal material of the selection material pattern is in a region adjacent to side surfaces of the selector material pattern.

According to an example embodiment, a semiconductor device includes a semiconductor substrate, first conductive lines extending in a first horizontal direction on the semiconductor substrate, second conductive lines on the first conductive lines and extending in a second horizontal direction perpendicular to the first horizontal direction, and a memory cell structure between the first conductive lines and the second conductive lines. The memory cell structure includes a first electrode pattern on the first conductive lines, a second electrode pattern on the first electrode pattern, and a data storage material pattern and a selector material pattern between the first electrode pattern and the second electrode pattern. The selector material pattern includes a first material, a second material, and a third material. The first material includes at least one of germanium (Ge), arsenic (As), and selenium (Se). The second material includes at least one of tellurium (Te), silicon (Si), indium (In), and gallium (Ga). The third material includes at least one of tungsten (W), titanium (Ti), aluminum (Al), and copper (Cu). A content of the first material and a content of the second material are each greater than a content of the third material.

### BRIEF DESCRIPTION OF DRAWINGS

The above and other aspects, features, and effects of the present disclosure will be more clearly understood from the following detailed description, taken in conjunction with the accompanying drawings.

FIG. 1 is a schematic perspective view of a semiconductor device according to example embodiments.

FIG. 2 is a schematic plan view of a semiconductor device according to example embodiments.

FIG. 3 is a schematic cross-sectional view of a semiconductor device according to an example embodiment.

FIG. 4A is a graph illustrating time-dependent variations of a threshold voltage of a selector material pattern of a semiconductor device according to example embodiments.

FIG. 4B is a graph illustrating operational durability of a selector material pattern of a semiconductor device according to example embodiments.

FIG. 5 is a schematic cross-sectional view illustrating a portion of components of a semiconductor device according to an example embodiment.

FIG. 6A is a schematic cross-sectional view of a semiconductor device according to an example embodiment.

FIG. 6B is a schematic cross-sectional view of a semiconductor device according to an example embodiment.

FIG. 6C is a schematic cross-sectional view of a semiconductor device according to an example embodiment.

FIG. 7 is a schematic cross-sectional view of a semiconductor device according to an example embodiment.

FIGS. 8A to 8D are cross-sectional views illustrating a method of manufacturing a semiconductor device according to an example embodiment.

FIG. 9 is a schematic view of an electronic system including a semiconductor device according to an example embodiment.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Expressions such as “at least one of,” when preceding a list of elements (e.g., A, B, and C), modify the entire list of elements and do not modify the individual elements of the list. For example, “at least one of A, B, and C,” “at least one of A, B, or C,” “one of A, B, C, or a combination thereof,” and “one of A, B, C, and a combination thereof,” respectively, may be construed as covering any one of the following combinations: A; B; A and B; A and C; B and C; and A, B, and C.”

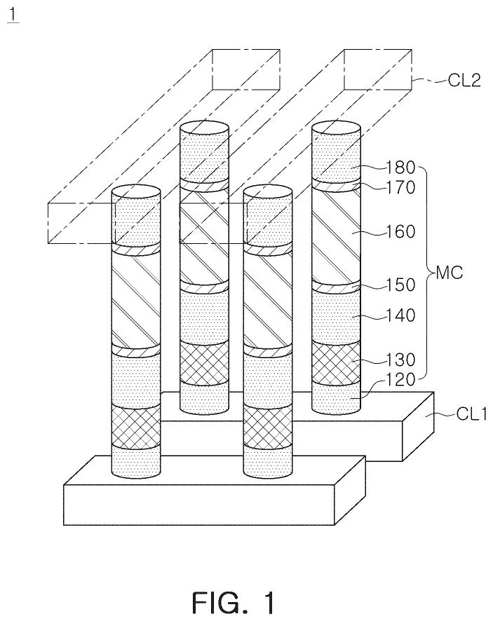

Hereinafter, a semiconductor device according to an example embodiment will be described with reference to FIGS. 1 to 3.

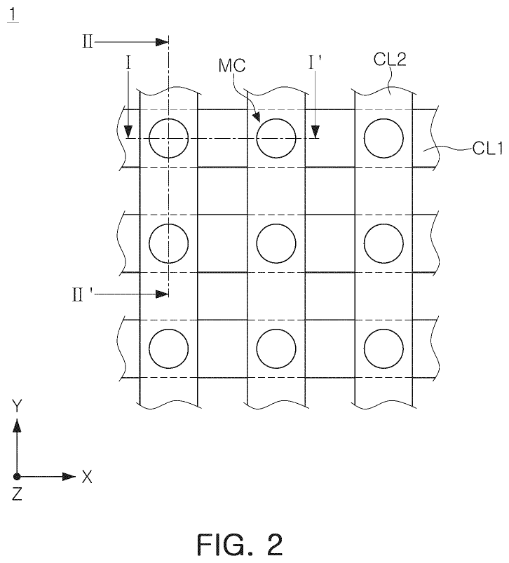

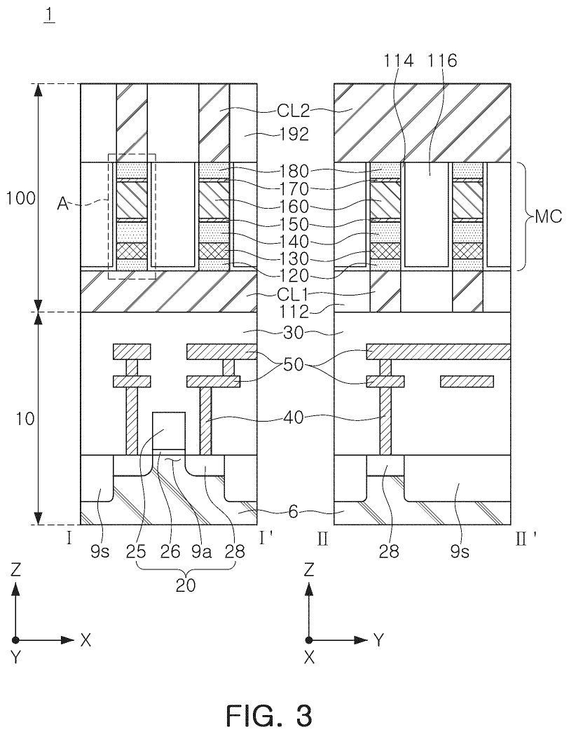

FIG. 1 is a schematic perspective view of a semiconductor device according to example embodiments. FIG. 2 is a schematic plan view of a semiconductor device according to example embodiments. FIG. 3 is a schematic cross-sectional view of a semiconductor device according to an example embodiment. FIG. 3 is a cross-sectional view taken along lines I-I′ and II-II′ of FIG. 2.

Referring to FIGS. 1 to 3, a semiconductor device 1 may include a lower structure 10 and an upper structure 100 on the lower structure 10. The upper structure 100 may include first conductive lines CL1, second conductive lines CL2, and a memory cell structure NC. The upper structure 100 is illustrated as being a single stacked structure including a memory cell structure MC, but the present disclosure is not limited thereto. The upper structure 100 may have a double stacked structure or a multi stacked structure (for example, quadruple stacked structure) in which memory cell structures MC are vertically arranged.

The lower structure 10 may include a semiconductor substrate 6, a circuit element 20 on the semiconductor substrate 6, a lower insulating structure 30 covering the circuit element 20 on the semiconductor substrate 6, and contact plugs 40 and circuit interconnections 50 disposed in the lower insulating structure 30 on the semiconductor substrate 60 and electrically connected to the circuit element 20.

The semiconductor substrate 6 may be a single-crystalline silicon substrate. An isolation layer 9s may be formed in the semiconductor substrate 6 to define an active region 9a.

The circuit elements 20 may include a gate electrode 25, a gate insulating layer 26, and source/drain regions 28. The gate electrode 25 may be disposed on the active regions 9a defined by the isolation layer 9s. The source/drain regions 28 may be formed in active regions 9a adjacent to opposite sides of the gate electrode 25. The gate insulating layer 26 may be disposed between the gate electrode 25 and the active region 9a. As an example, a spacer layer may be further disposed on both sidewalls of the gate electrode 25.

The lower insulating structure 30 may be disposed on the circuit element 20 on the semiconductor substrate 6. The circuit contact plugs 40 may be connected to the source/drain regions 28 through a portion of the lower insulating structure 30. An electrical signal may be applied to the circuit element 20 by the circuit contact plugs 40. The circuit interconnections 50 may be connected to the circuit contact plugs 40, and may be disposed as a plurality of layers. The circuit element 20 may be connected to the first conductive lines CL1 or the second conductive lines CL2 through additional contact plugs.

The first conductive lines CL1 may extend upwardly of the semiconductor substrate 6 in a first horizontal direction X, and may be disposed to be spaced apart from each other in a second horizontal direction Y. The first conductive lines CL may include a plurality of conductive lines disposed to be parallel to each other. The first horizontal direction X and the second horizontal direction Y may be perpendicular to each other.

The second conductive lines CL2 may extend upwardly of the first conductive lines CL1 in the second horizontal direction Y, and may be disposed to be spaced apart from each other. The second conductive lines CL2 may include a plurality of conductive lines disposed to be parallel to each other.

As an example, a thickness of each of the second conductive lines CL2 may be greater than a thickness of each of the first conductive lines CL1. For example, a thickness of each of the second conductive lines CL2 may be about two to three times a thickness of each of the first conductive lines CL1, but the present disclosure is not limited thereto.

As an example, one of the first conductive lines CL1 and the second conductive lines CL2 may be wordlines, and the other may be bitlines. As an example, the first conductive lines CL may be wordlines, and second conductive lines CL2 may be bitlines. As another example, the first conductive lines CL1 may be bitlines, and the second conductive lines CL2 may be wordlines.

As an example, each of the first conductive lines CL may include a first lower conductive layer and a second lower conductive layer sequentially stacked. The first lower conductive layer may be formed as a barrier layer such as a titanium nitride, a tungsten nitride, or the like, and the second lower conductive layer may be formed of a metal material such as tungsten (W), titanium (Ti), aluminum (Al), copper (Cu), or the like. The second conductive lines CL2 may also include a first upper conductive layer and a second upper conductive layer sequentially stacked. The first upper conductive layer may be formed as the barrier layer, and the second upper conductive layer may be formed of a metal material such as tungsten (W), titanium (Ti), aluminum (Al), copper (Cu), or the like.

As an example, the upper structure 100 may further include first insulating patterns 112 on side surfaces of the first conductive lines CL1 and second insulating patterns 192 on side surfaces of the second conductive lines CL2. The first insulating patterns 112 may be disposed to extend between the first conductive lines CL1 in the first horizontal direction X. The second insulating patterns 192 may be disposed to extend between the second conductive lines CL2 in the second horizontal direction Y. The first insulating patterns 112 may be repeatedly arranged alternately with the first conductive lines CL1 in the second direction Y. The second insulating patterns 192 may be repeatedly arranged alternately with the second conductive lines CL2 in the first direction X. The first insulating patterns 112 and the second insulating patterns 192 may include at least one of SiN, SiON, SiC, SiCN, SiOC, SiOCN, SiO₂, and Al₂O₃.

The memory cell structure MC may include N electrode patterns (where N is an integer of 3 or more), a data storage material pattern 160, and a selector material pattern 130 overlapping in a vertical direction, For example, the memory cell structure MC may include a first electrode pattern 120, the selector material pattern 130, intermediate electrode patterns 140 and 150, the data storage material pattern 160, and second electrode patterns 170 and 180, which are sequentially stacked on the first conductive lines CL.

The memory cell structure MC may have a structure in which a plurality of patterns have central portions matching each other in a vertical direction Z. For example, the selector material pattern 130 and the data storage material pattern 160 may overlap each other in the vertical direction Z. The selector material pattern 130 and the data storage material pattern 160 may be arranged in a region in which the first conductive lines CL1 and the second conductive lines CL2 intersect each other.

The memory cell structure MC may include a plurality of patterns having, for example, a quadrangular shape such a square or a rectangle, or a circular shape, when viewed from above.

The first electrode pattern 120 may be disposed between the first conductive lines CL1 and the selector material pattern 130. The second electrode patterns 170 and 180 may be disposed between the data storage material pattern 160 and the second conductive lines CL2. The intermediate electrode patterns 140 and 150 may be disposed between the selector material pattern 130 and the data storage material pattern 160.

The first electrode pattern 120 may be a carbon material layer or a carbon-containing material layer. As an example, the carbon-containing material layer may be a material layer in which at least one of a nitrogen element and a metal element is contained in a carbon material layer. For example, the carbon-containing material layer may be formed of a conductive material including a metal-based metal element, such as a W-based metal element or a Ti-based metal element, and a carbon element, for example, a metal-carbon alloy material such as a tungsten carbide (WC) or a titanium carbide (TiC). The metal element of the metal-carbon alloy material is not limited to W and Ti, and may include another metal element (for example, Ta, Co, or the like) capable of forming an alloy with carbon (C).

Hereinafter, it will be understood that, as described above, a carbon-containing material layer is a conductive material layer including a carbon element with at least one of a nitrogen element and a metal element, unless described additionally.

The intermediate electrode patterns 140 and 150 may include a first intermediate electrode layer 140 and a second intermediate electrode layer 150 sequentially stacked. The intermediate electrode layer 140 may have a greater thickness than a thickness of the second intermediate electrode layer 150. The first intermediate electrode layer 140 may be in contact with the selector material pattern 130, and the second intermediate electrode layer 150 may be in contact with the data storage material pattern 160. The first intermediate electrode layer 140 may be a carbon material layer or a carbon-containing material layer, and the second intermediate electrode layer 150 may be a metal layer or a metal-alloy layer. For example, the second intermediate electrode layer 150 may include a conductive material such as W, WN, TiN, or the like.

The second electrode patterns 170 and 180 may include a first upper electrode layer 170 and a second upper electrode layer 180 sequentially stacked. The first upper electrode layer 170 may have a smaller thickness than a thickness of the second upper electrode layer 180. The first upper electrode layer 170 may be in contact with the data storage material pattern 160, and the second upper electrode layer 180 may be in contact with the second conductive line CL2. The first upper electrode layer 170 may include a conductive material such as W, WN, TiN, or the like. The second upper electrode layer 180 may be a carbon material layer or a carbon-containing material layer.

The selector material pattern 130 may be disposed between the first electrode pattern 120 and the intermediate electrode patterns 140 and 150. The selector material pattern 130 may constitute an ovonic threshold switching device.

As an example, the selector material pattern 130 may be formed of a chalcogenide-based ovonic threshold switching material maintaining an amorphous phase when a semiconductor device operates.

For example, the selector material pattern 130 may include an alloy material, including at least two or more elements among As, S, Se, Te, and Ge, or an additional element (for example, Si, N, or the like) maintaining the amorphous phase at a higher temperature in addition to the alloy material

As a detailed example, the selector material pattern 130 may include at least one composition, among a binary composition such as GeSe, GeS, AsSe, AsTe, AsS SiTe, SiSe, SiS, GeAs, SiAs, SnSe, and SnTe, a ternary composition such as GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe, a quaternary composition such as GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, and GeAsTeZn, a quinary composition such as GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, and GeAsSeZnSn, and a senary composition such as GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn.

As an example, the compositions may include at least one of B, C, N, and O in small amount. In an example embodiment, the selector material pattern 130 may have a multilayer structure including two or more layers having different compositions.

As an example, the selector material pattern 130 may be formed of a single switching material layer. As another example, the selector material pattern 130 may be formed of a plurality of layers having different compositions each other.

The data storage material pattern 160 may be disposed between the intermediate patterns 140 and 150 and the second electrode patterns 170 and 180.

As an example, a thickness of the data storage material pattern 160 may be about two to about four times greater than a thickness of the selector material pattern 130.

The data storage material pattern 160 may include a phase change material changing from a crystalline state to an amorphous state or changing from an amorphous state to a crystalline state. For example, the data storage material pattern 160 may include a phase change material such as a chalcogenide material including Ge, Sb, and/or Te. For example, the data storage material pattern 160 may include a phase change material including at least one of Te and Se and at least one of Ge, Sb, Bi, Pb, Sn, As, S, Si, P, O, N, and In.

As a detailed example, the data storage pattern 160 may include at least one composition, among a binary composition such as GeTe, GeSe, GeS, SbSe, SbTe, SbS, SbSe, SnSb, InSe, InSb, AsTe, AlTe, GaSb, AlSb, BiSb, ScSb, Ysb, CeSb, DySb, and NdSb, a ternary composition such as GeSbSe, AlSbTe, AlSbSe, SiSbSe, SiSbTe, GeSeTe, InGeTe, GeSbTe, GeAsTe, SnSeTe, GeGaSe, BiSbSe, GaSeTe, InGeSb, GaSbSe, GaSbTe, InSbSe, InSbTe, SnSbSe, SnSbTe, ScSbTe, ScSbSe, ScSbS, YSbTe, YSbSe, YSbS, CeSbTe, CeSbSe, CeSbS, DySbTe, DySbSe, DySbS, NdSbTe, NdSbSe, and NdSbS, a quaternary composition such as GeSbTeS, BiSbTeSe, AgInSbTe, GeSbSeTe, GeSnSbTe, SiGeSbTe, SiGeSbSe, SiGeSeTe, BiGeSeTe, BiSiGeSe, BiSiGeTe, GeSbTeBi, GeSbSeBi, GeSbSeIn, GeSbSeGa, GeSbSeAl, GeSbSeTl, GeSbSeSn, GeSbSeZn, GeSbTeIn, GeSbTeGa, GeSbTeAl, GeSbTeTl, GeSbTeSn, GeSbTeZn, ScGeSbTe, ScGeSbSe, ScGeSbS, YGeSbTe, YGeSbSe, YGeSbS, CeGeSbTe, CeGeSbSe, CeGeSbS, DyGeSbTe, DyGeSbSe, DyGeSbS, NdGeSbTe, NdGeSbSe, and NdGeSbS, and a quinary composition such as InSbTeAsSe, GeScSbSeTe, GeSbSeTeS, GeScSbSeS, GeScSbTeS, GeScSeTeS, GeScSbSeP, GeScSbTeP, GeSbSeTeP, GeScSbSeIn, GeScSbSeGa, GeScSbSeAl, GeScSbSeTl, GeScSbSeZn, GeScSbSeSn, GeScSbTeIn, GeScSbTeGa, GeSbAsTeAl, GeScSbTeTl, GeScSbTeZn, GeScSbTeSn, GeSbSeTeIn, GeSbSeTeGa, GeSbSeTeAl, GeSbSeTeTl, GeSbSeTeZn, GeSbSeTeSn, GeSbSeSIn, GeSbSeSGa, GeSbSeSAl, GeSbSeSTl, GeSbSeSZn, GeSbSeSSn, GeSbTeSIn, GeSbTeSGa, GeSbTeSAl, GeSbTeSTl, GeSbTeSZn, GeSbTeSSn, GeSbSeInGa, GeSbSeInAl, GeSbSeInTl, GeSbSeInZn, GeSbSeInSn, GeSbSeGaAl, GeSbSeGaTl, GeSbSeGaZn, GeSbSeGaSn, GeSbSeAlTl, GeSbSeAlZn, GeSbSeAlSn, GeSbSeTlZn, GeSbSeTlSn, and GeSbSeZnSn.

As an example, the compositions may include at least one of B, C, N, O, P, Cd, W, Ti, Hf, and Zr in a small amount. As an example, the data storage material pattern 160 may have a multilayer structure including two or more layers having different compositions.

The semiconductor device 1 according to example embodiments may further include spacer layers 114, covering side surfaces of the memory cell structure MC, and an interlayer insulating layer 116 filling a space between the memory cell structures MC on the first conductive lines CL1 and the first insulating patterns 112. The spacer layers 114 may cover a portion of upper surfaces of the first conductive lines CL1 and a portion of upper surfaces of the first insulating patterns 112.

As an example, the spacer layers 114 may include at least one of SiN, SiO₂, SiON, SiBN, SiCN, SiOCN, Al₂O₃, AlN, and AlON. The spacer layers 114 may include a plurality of layers.

As an example, the interlayer insulating layer 116 may include at least one of SiN, SiON, SiC, SiCN, SiOC, SiOCN, SiO₂, and Al₂O₃. The interlayer insulating layer 116 may include a plurality of layers.

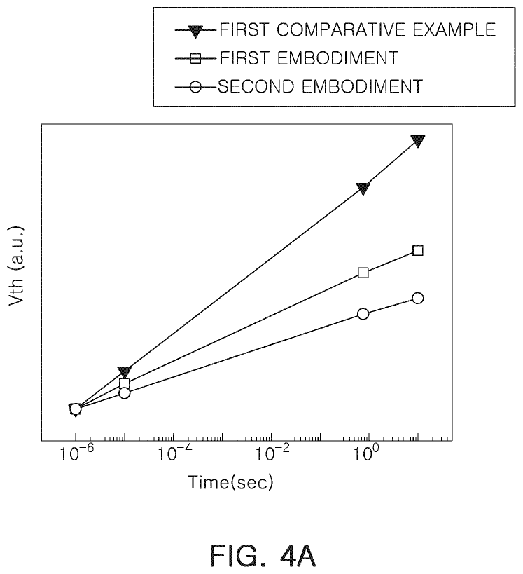

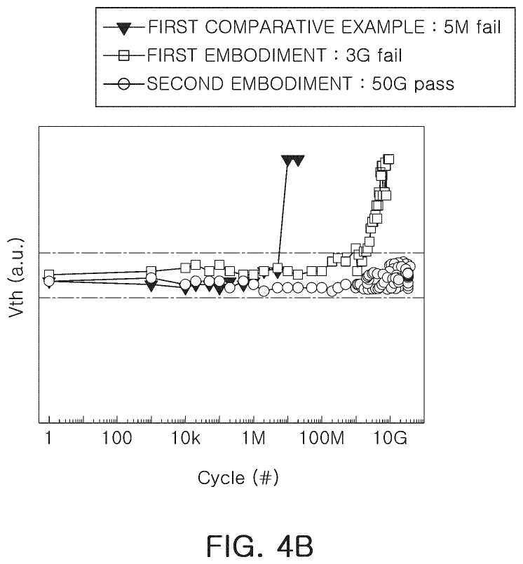

FIG. 4A is a graph illustrating time-dependent variations of a threshold voltage of a selector material pattern of a semiconductor device according to example embodiments.

FIG. 4B is a graph illustrating operational durability of a selector material pattern of a semiconductor device according to example embodiments.

Referring to Table 1 below, various embodiments in which a composition of the selector material pattern 130 varies will be described.

TABLE 1
Physical properties and operational durability of selector material patterns
according to comparative example and embodiments

| | First | | | | | |
|---|---|---|---|---|---|---|
| | Comparative | Example Embodiments | | | | |
| | Example | First | Second | Third | Fourth | Fifth |
| Tₛ (° C.) | 225 | 250 | 275 | 275 | 275 | 275 |
| T_{g} (° C.) | 325 | 350 | 375 | 375 | 350 | 375 |
| T_{c} (° C.) | ≥450 | ≥450 | ≥450 | ≥450 | ≥450 | ≥450 |
| I_{off} (nA) | 1.5 | 1.4 | 1.0 | 1.2 | 1.0 | 1.0 |
| Vₜₕ drift | 70 | 40 | 35 | ≤25 | ≤25 | ≤25 |
| (mV/dec) | | | | | | |
| Intrinsic | ~5E+6 | 3E+9 | _≥5E+10 | ≥1E+10 | ≥1E+10 | ≥1E+10 |
| Read | | | | | | |
| Endurance | | | | | | |
| (# cycle) | | | | | | |

In the first embodiment, a threshold switching material of the selector material pattern 130 may be a Ge_{α}As_{β}Se_{γ}Te_{δ}Si_{η} material. Here, α may be in the range of about 13 atomic % to about 23 atomic %, β may be in the range of about 25 atomic % to about 35 atomic %, γ may be in the range of about 38 atomic % to about 50 atomic %, δ may be in the range of about 0.1 atomic % to about 6 atomic %, and η may be in the range of about 0.1 atomic % to about 8 atomic %.

In the second embodiment, a threshold switching material of the selector material pattern 130 may be a Ge_{α}As_{β}Se_{γ}In_{η} material. Here, α may be in the range of about 13 atomic % to about 23 atomic %, β may be in the range of about 25 atomic % to about 35 atomic %, γ may be in the range of about 38 atomic % to about 50 atomic %, and η may be in the range of about 0.1 atomic % to about 6 atomic %.

In the third embodiment, a threshold switching material of the selector material pattern 130 may be a Ge_{α}As_{β}Se_{γ}Si_{η}In_{δ} material. Here, α may be in the range of about 13 atomic % to about 23 atomic %, β may be in the range of about 25 atomic % to about 35 atomic %, γ may be in the range of about 38 atomic % to about 50 atomic %, η may be in the range of about 0.1 atomic % to about 8 atomic %, and δ may be in the range of about 0.1 atomic % to about 6 atomic %.

In the fourth embodiment, a threshold switching material of the selector material pattern 130 may be a Ge_{α}As_{β}Se_{γ}Ga_{η} material. Here, α may be in the range of about 13 atomic % to about 23 atomic %, β may be in the range of about 25 atomic % to about 35 atomic %, γ may be in the range of about 38 atomic % to about 50 atomic %, and η may be in the range of about 0.1 atomic % to about 6 atomic %.

In the fifth embodiment, a threshold switching material of the selector material pattern 130 may be a Ge_{α}As_{β}Se_{γ}Ga_{η}In_{δ} material. Here, α may be in the range of about 13 atomic % to about 23 atomic %, β may be in the range of about 25 atomic % to about 35 atomic %, γ may be in the range of about 38 atomic % to about 50 atomic %, η may be in the range of about 0.1 atomic % to about 6 atomic %, and δ may be in the range of about 0.1 atomic % to about 6 atomic %.

In the first to fifth embodiments discussed above, a sum of the atomic percentages for elements in the selector material pattern 130 may add up to 100 atomic % or less, but not more than 100 atomic %. For example, in the Ge_{α}As_{β}Se_{γ}Te_{δ}Si_{η} material of the first embodiment, a sum of α, β, γ, δ, and η may be 100 atomic % or less. As another example, in the Ge_{α}As_{β}Se_{γ}In_{η} material of the second embodiment, a sum of α, β, γ, and η may be 100 atomic % or less. In the Ge_{α}As_{β}Se_{γ}Si_{η}In_{δ} material of the third embodiment, a sum of α, β, γ, η, and δ may be 100 atomic % or less. In the Ge_{α}As_{β}Se_{γ}Ga_{η} material of the fourth embodiment, a sum of α, β, γ, and η may be 100 atomic % or less. In the Ge_{α}As_{β}Se_{γ}Ga_{η}In_{δ} material of the fifth embodiment, a sum of α, β, γ, η, and δ may be 100 atomic % or less.

Table 1 illustrates physical properties and operational durability depending on threshold switching materials of selector material patterns 130 according to the above-described first to fifth embodiments, as compared with the first Comparative Example. The first Comparative Example indicates a case in which elements such as Te, Si, In, Ga, and the like, are not included as threshold switching materials.

Referring to Table 2 below, table 2 illustrates bonding energy of Se to Si, In, and Ga, dopants, and oxide formation enthalpy.

TABLE 2
Bonding energy and oxide formation enthalpy with Se for each dopant

| | Bonding Energy (E_{b}) | Oxide Formation Enthalpy |
|---|---|---|
| Dopant | [KJ/mol] | [KJ/mol] |
| Si | 531 | −220 |
| In | 247 | −70 |
| Ga | 321 | −165 |

In the first to fifth embodiments, a volatilization temperature Tₛ and the vitrification temperature Tg are increased, as compared with the first Comparative Example. Referring to Table 2, the Si element, the In element, and the Ga element having high bonding strength may bond to the Se element to increase thermal stability of the threshold switching material. In the first to fifth embodiments, the selector material pattern 130 may include dopants of the Si element, the In element, and the Ga element at a content in the desired and/or alternatively predetermined range to limit and/or prevent a decreasing in band gap energy or crystallization of an entire layer.

In the first to fifth embodiments, a volatilization temperature of the threshold switching material of the selector material pattern 130 may be about 250° C. or higher. In the first to fifth embodiments, a vitrification temperature of the threshold switching material of the selector material pattern 130 may be about 350° C. or higher.

In addition, the referring to Table 2, oxide formation enthalpy of the In element may have a small value of, value of oxide formation enthalpy of the Si element may have a greatest value, and value of oxide formation enthalpy of the Ga element may have an intermediate value between the values of the oxide formation enthalpy of the In element and the Si element. The term “oxide formation enthalpy” refers to a value representing the degree of stability in an oxide state. The higher the oxide formation enthalpy, the more oxidation is readily performed and the more an oxide is stable. Since the In element has less bonding strength to Se element than Si element but has low oxide formation enthalpy, the In element may significantly reduce oxide formation, and all In elements may participate in bonding to the Se element and may improve thermal stability, electrical characteristics and operational durability of the threshold switching material.

In the first to fifth embodiments, leakage current I_{off} is decreased and the amount of variation in a threshold voltage Vₜₕ is decreased, as compared with the first Comparative Example. The amount of variation in the threshold voltage Vₜₕ represents a value of time-dependent variations of the threshold voltage Vₜₕ. The improvement in characteristics of the leakage current I_{off} and the threshold voltage Vₜₕ may result from an increase in thermal stability of the threshold switching material which is achieved by including dopants of the Si element, the In element, and/or the Ga element in the selector material pattern 130 at the content in the above-described range.

Referring to FIG. 4A together, a time-dependent variations of a threshold voltage of a selector material pattern in the first Comparative Example and the first and second embodiments may be confirmed. In FIG. 4A, the amount of variation in a threshold voltage, defined as a slope, represents the degree of variation in the threshold voltage per decade. The first and second embodiments have a smaller slope value, the amount of variation in the threshold voltage, than the first Comparative Example. In addition, the second embodiment has a smaller slope value, the amount of variation in the threshold voltage, than the first embodiment. Referring to Table 1, in the first embodiment, the amount of variation in a threshold voltage of the selector material pattern 130 may be less than or equal to about 40 mV/dec. In the second embodiment, the amount of variation in the threshold voltage of the selector material pattern 130 may be less than about 35 mV/dec. In the third to fifth embodiments, the amount of variation in the threshold voltage of the selector material pattern 130 may be less than about 25 mV/dec.

In the first to fifth embodiments, operational durability may be improved, as compared with the first Comparative Example. The improvement in the operational durability may result from an increase in thermal stability of the threshold switching material which is achieved by including the dopant of the Si element, the In element, and/or the Ga element in the selector material pattern 130 at the content in the above-described range. In particular, in the first embodiment, the number of operations until significant variation of the threshold voltage was increased by about 600 times or more, as compared with the first Comparative Example. In the second embodiment, the number of operations until significant variation of the threshold voltage was increased by about 1000 times or more.

Referring to FIG. 4B together, operational durability of the selector material pattern in the first Comparative Example and the first and second embodiment may be confirmed. In the first Comparative Example, the number of operations until significant variation of the threshold voltage was about 5×10⁶. In the first embodiment, the threshold voltage significantly varied at the number of operations of about 3×10⁹. In the second embodiment, the threshold voltage did not significantly varied and was maintained within a desired and/or alternatively predetermined range at the number of operations of about 5×10⁹ or more. For example, as compared with the first Comparative Example, the selector material pattern 130 may further include elements such as Te, Si, In, and Ga to improve operational durability of the selector material pattern 130.

In the semiconductor device 1 according to the example embodiment, the selector material pattern 130 may further include a metal material. For example, the metal material of the selector material pattern 130 may include at least one of tungsten (W), titanium (Ti), aluminum (Al), and copper (Cu). The metal material may be a metal material common with the first conductive lines CL1 or the second conductive lines CL2. For example, the selector material pattern 130 may include tungsten (W), a metal material in common with the first conductive lines CL1 and the second conductive lines CL2.

As an example, the metal material of the selector material pattern 130 may be distributed in regions adjacent to side surfaces of the selector material pattern 130. Metal materials, generated by etching a portion of the first conductive lines CL1 or the second conductive lines CL2, may be redeposited on the side surfaces of the selector material pattern 130.

As an example, the content of the metal material may be greater than 0 atomic % and less than about 2 atomic %.

As an example, the content of the metal material may be greater than 0.1 atomic % and less than about 2.1 atomic %.

As an example, the content of the metal material may be greater than 1 atomic % and less than about 2.5 atomic %.

TABLE 3
Variations of operational durability depending on content of
metal element of selector material pattern

| | Second | |
|---|---|---|
| | Comparative | Example |
| | Example | Embodiment |
| Composition (EDS) of tungsten (W) | 2.8 | 1.9 |
| Write Operational durability (# cycle) | <3E+3 | >1E+5 |

Table 3 illustrates operational durability of a threshold switching device depending on the content of a metal element included in the selector material pattern 130. In the case of the second Comparative Example, the content of a metal element (for example, tungsten (W)) included in the selector material pattern 130 is about 2.8 atomic %, and the number of operations repeated until significant variation of a threshold voltage is less than about 3×10³. On the other hand, in an example embodiment, a threshold voltage significantly varies when the content of a metal element (for example, tungsten (W)) included in the selector material pattern 130 is about 1.9 atomic %. The number of repeated operations is greater than about 10⁵. For example, when the content of the metal element included in the selector material pattern 130 is less than about 2 atomic %, deterioration in operational durability may be reduced.

When each of the Ge_{α}As_{β}Se_{γ}Te_{δ}Si_{η} material, the Ge_{α}As_{β}Se_{γ}In_{η} material, the Ge_{α}As_{β}Se_{γ}Si_{η}In_{δ} material, the Ge_{α}As_{β}Se_{γ}Ga_{η}material, and the Ge_{α}As_{β}Se_{γ}Ga_{η}In_{δ} material of the selector material pattern 130 has the above-described composition ratio in the first to fifth embodiments and the content of the metal element included in the selector material pattern 130 is within about 2 atomic %, physical properties and operational durability of the selector material pattern 130 may be improved, as compared with the first Comparative Example, without deteriorating the physical properties and operational durability of the selector material pattern 130.

As an example, the selector material pattern 130 may include a first material including at least one of Ge, As, and Se, and a second material including at least one of Te, Si, In, and Ga, and a third material including at least one of W, Ti, Al, and Cu. The content of the first material and the content of the second material may each be greater than the content of the third material. The content of the first material may be greater than the content of the second material. The content of the third material may be greater than 0 atomic % of the total content of the first to third materials, and may be less than about 2 atomic %.

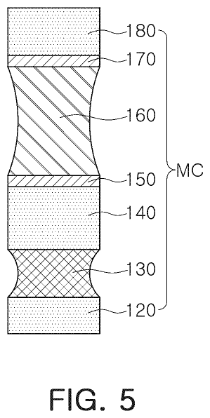

FIG. 5 is a schematic cross-sectional view illustrating a portion of components of a semiconductor device according to an example embodiment.

Referring to FIG. 5, a selector material pattern 130 may have a concave side surface in a direction toward a central axis of the selector material pattern 130. The central axis of the selector material pattern 130 may refer to a central axis between both side surfaces of the selector material pattern 130. A data storage material pattern 160 may have a concave side surface in a direction toward the central axis of the selector material pattern 130. Such shapes of the selector material pattern 130 and the data storage material pattern 160 may be equivalently applied to various embodiments of the present specification.

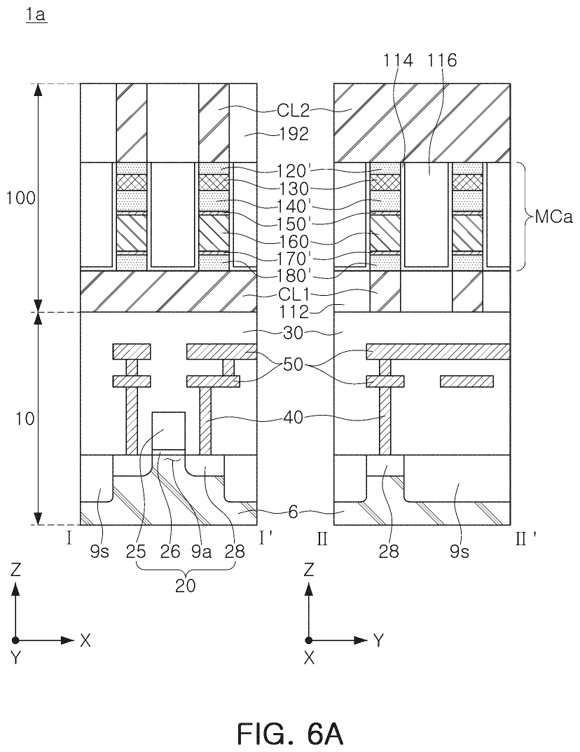

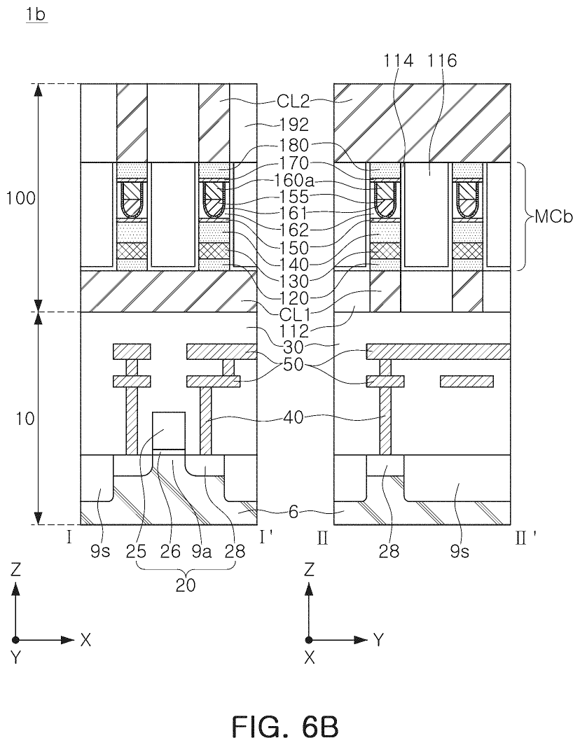

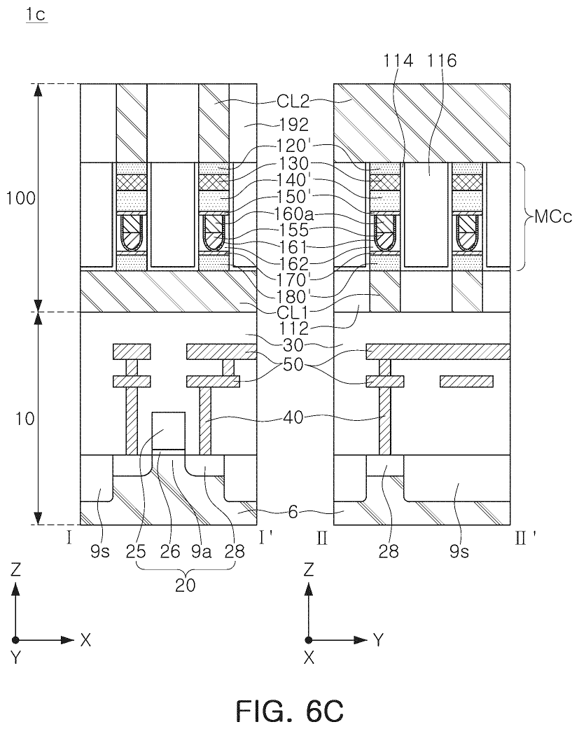

FIGS. 6A to 6C are schematic cross-sectional views of a semiconductor device according to an example embodiment. FIGS. 6A to 6C illustrate regions corresponding to the cross-sectional view of FIG. 3.

Referring to FIG. 6A, in a semiconductor device 1a, the stacking order of a memory cell structure MCa may be changed. The memory cell structure MCa may include second electrode patterns 170′ and 180′, data storage material patterns 160, intermediate electrode patterns 140′ and 150′, a selector material pattern 130, and a first electrode pattern 120′, which are sequentially stacked on a first conductive lines CL1. The selector material pattern 130 may be disposed on a higher level than the data storage material pattern 160. In the present specification, such a level may be defined based on an upper surface of a semiconductor substrate 6.

The second electrode patterns 170′ and 180′ may include a first lower electrode layer 170′ and a second lower electrode layer 180′. The first lower electrode layer 170′ may have a smaller thickness than the second lower electrode layer 180′. The intermediate electrode pattern 140′ and 150′ may include a first intermediate electrode layer 140′ and a second intermediate electrode layer 150′. The second intermediate electrode layer 150′ may have a smaller thickness than the first intermediate electrode layer 140′. The second lower electrode layer 180′, the first intermediate electrode layer 140′, and the first electrode layer 120′ may be a carbon material layer or a carbon-containing material layer described above. The first lower electrode layer 170′ and the second intermediate electrode layer 150′ may be a metal layer or metal alloy layer described above.

Referring to FIG. 6B, in a semiconductor device 1b, a memory cell structure MCb may include a barrier layer 161, disposed in a recess of a spacer 162, and a lower conductive layer 155 and a data storage material pattern 160a filing an internal space of the barrier layer 161 within the recess. The data storage material pattern 160a may be disposed on the lower conductive layer 155. The lower conductive layer 155 may include metal nitride such as titanium nitride (TiN) and tungsten nitride (WN). The recess may have a U shape or a U-like shape. The recess may be formed by forming an insulating layer and removing a portion of the insulating layer from an upper portion in a location corresponding to the memory cell structure MCb.

Referring to FIG. 6C, in a semiconductor device 1c, the stacking order of a memory cell structure MCc may be changed. In the semiconductor device 1c, the spacer 162, the barrier layer 161, the lower conductive layer 155, and the data storage material pattern 160a of the semiconductor device 1b of FIG. 6B may be disposed on a lower level than a selector material pattern 130.

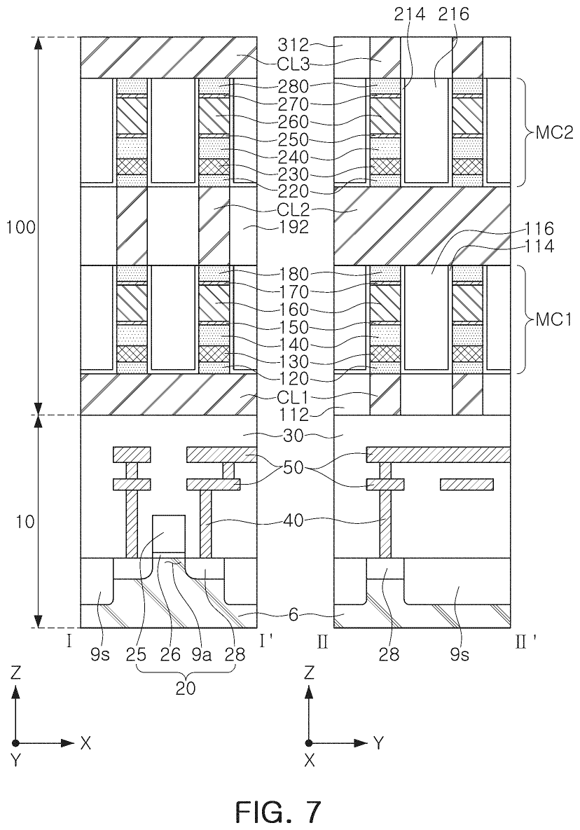

FIG. 7 is a schematic cross-sectional view of a semiconductor device according to an example embodiment. FIG. 7 illustrates a region corresponding to the cross-sectional view of FIG. 3.

Referring to FIG. 7, an upper structure 100 may include first conductive lines CL1, a first memory cell structure MC1, and second conductive lines CL2, and may further include second memory cell structure MC2 and third conductive lines CL3 disposed on second conductive lines CL2. The second memory cell structure MC2 may be arranged to overlap the first memory cell structure MC1 in a vertical direction Z. The second memory cell structure MC2 may have a structure similar to a structure of the first memory cell structure MC1. For example, the second memory cell structure MC2 may also include a first electrode pattern 220, a selector material pattern 230, intermediate electrode patterns 240 and 250, a data storage material pattern 260, and second electrode patterns 270 and 280, which are sequentially stacked on the second conductive lines CL2. Third conductive lines CL3 may extend in a first horizontal direction X, and may be disposed to be spaced apart from each other in a second horizontal direction Y. The upper structure 100 may further include third insulating patterns 312 between the third conductive lines CL3, second spacer layers 214 covering side surfaces of the second memory cell structure MC2, and a second interlayer insulating layer 216 filling a space between the memory cell structures MC2.

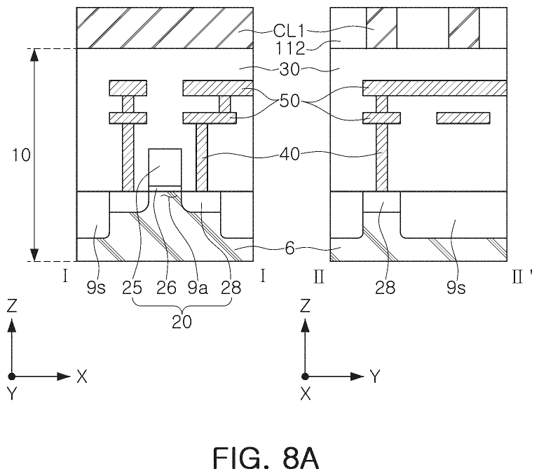

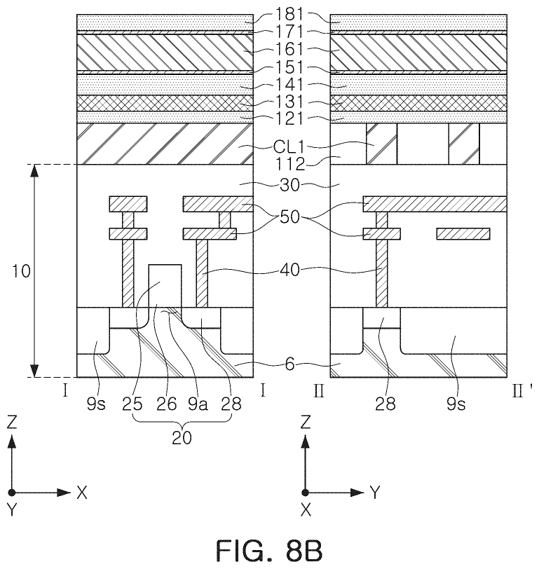

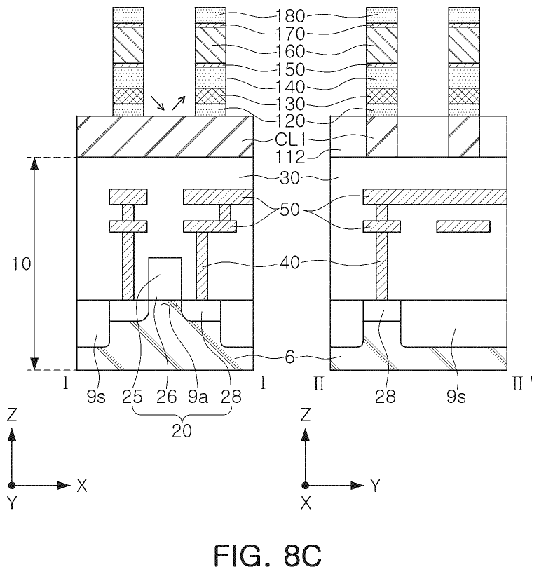

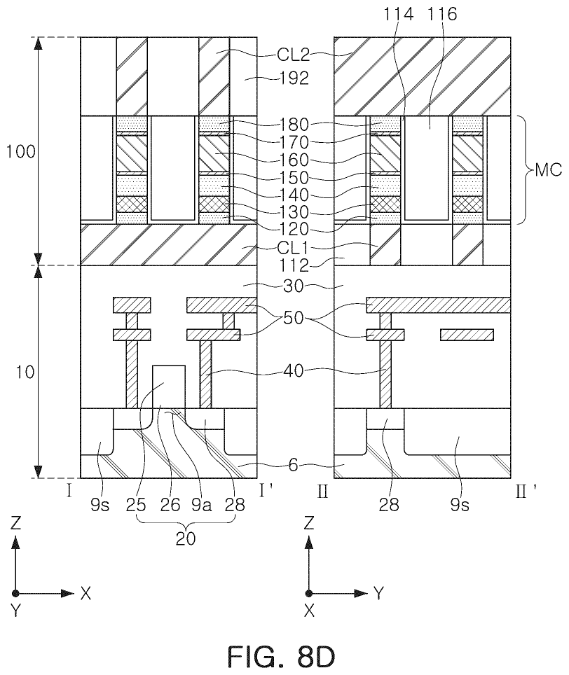

FIGS. 8A to 8D are cross-sectional views illustrating a method of manufacturing a semiconductor device according to an example embodiment.

Referring to FIG. 8A, a lower structure 10 may be formed, and then first conductive lines CL1 and first insulating patterns 112 may be formed.

The forming of the lower structure 10 may include preparing a semiconductor substrate 6, forming an isolation layer 9s to define an active region 9a in the semiconductor substrate 6, and forming circuit elements 20 and lower insulating structure 30 on the semiconductor substrate 6. The circuit elements 20 may include a gate electrode 25, a gate insulating layer 26, and source/drain regions 28, as described in FIG. 3. The lower insulating structure 30 may cover the circuit elements 20. Circuit contact plugs 40 and circuit interconnections 50 may be formed in the lower insulating structure 30.

First conductive lines CL1 may be formed on the lower insulating structure 30. The forming of the first conductive lines CL1 may include forming a conductive layer and patterning the conductive layer. The first conductive lines CL1 may be formed to extend in a first horizontal direction X. First insulating patterns 112 may be formed between the first conductive lines CL1. The first insulating patterns 112 may be formed to extend in the first horizontal direction X. The forming of the first conductive lines CL1 may include forming a first lower conductive layer and a second lower conductive layer.

Referring to FIG. 8B, a plurality of layers 121, 131, 141, 151, 161, 171, and 181 may be formed on the first conductive lines CL1 and the first insulating patterns 112.

A portion of the plurality of layers 121, 131, 141, 151, 161, 171, and 181 may be etched in a subsequent process to constitute a memory cell structure MC. The plurality of layers 121, 131, 141, 151, 161, 171, and 181 may be formed to have different thicknesses, or some of plurality of layers 121, 131, 141, 151, 161, 171, and 181 the may be formed to have substantially the same thickness.

Referring to FIG. 8C, the plurality of layers 121, 131, 141, 151, 161, 171, and 181 may be patterned to form a memory cell structure MC.

In the plurality of layers 121, 131, 141, 151, 161, 171, and 181, an external region in a location corresponding to the memory cell structure MC of FIG. 3 may be removed to form a first electrode pattern 120, a selector material pattern 130, intermediate electrode patterns 140 and 150, a data storage material pattern 160, and a second electrode patterns 170 and 180.

In this case, a portion of the first conductive lines CL1 may be exposed in the etching process of the plurality of layers 121, 131, 141, 151, 161, 171, and 181. A metal element, included in the first conductive lines CL1, may be redeposited on the memory cell structure MC by an etchant used in the etching process. The metal element may include at least one of tungsten (W), titanium (Ti), aluminum (Al), and copper (Cu). The content of the metal element redeposited on the selector material pattern 130 may be in the range of about 2 atomic %. The content of the metal element included in the selector material pattern 130 may be limited to about 2 atomic % or less to limit and/or prevent deterioration of the operational durability of the selector material pattern 130 as a threshold switching device.

As another example, the forming of the memory cell structure MC may include patterning the plurality of layers 121, 131, 141, 151, 161, 171, and 181 in a first horizontal direction X, filling a region, in which the plurality of layers 121, 131, 141, 151, 161, 171, and 181 are removed, with an insulating layer, forming second conductive layers, and patterning the second conductive layer, the insulating layer, and the plurality of layers 121, 131, 141, 151, 161, 171, and 181. Thus, the second conductive layer may be formed as second conductive lines CL2, and the plurality of layers 121, 131, 141, 151, 161, 171, and 181 may each be formed as a memory cell structure MC in a region in which the first conductive lines CL1 and the second conductive lines CL2 intersect each other.

Referring to FIG. 8D, an interlayer insulating layer 116 may be formed, and second conductive lines CL2 and second insulating patterns 192 may be formed.

The interlayer insulating layer 116 may fill a space between the memory cell structures MC on the first conductive lines CL1 and the first insulating patterns 112. Before the interlayer insulating layer 116 is formed, a spacer layer 114 may be formed to cover sidewalls of the memory cell structures MC.

Second conductive lines CL2 may be formed on the memory cell structure MC. The forming of the second conductive lines CL2 may include forming a conductive layer and patterning the conductive layer. The second conductive lines CL2 may be formed to extend in a second horizontal direction Y. Second insulating patterns 192 may be formed between the second conductive lines CL2. The second insulating patterns 192 may be formed to extend in the second horizontal direction Y. The forming of the second conductive lines CL2 may include forming a first upper conductive layer and a second upper conductive layer.

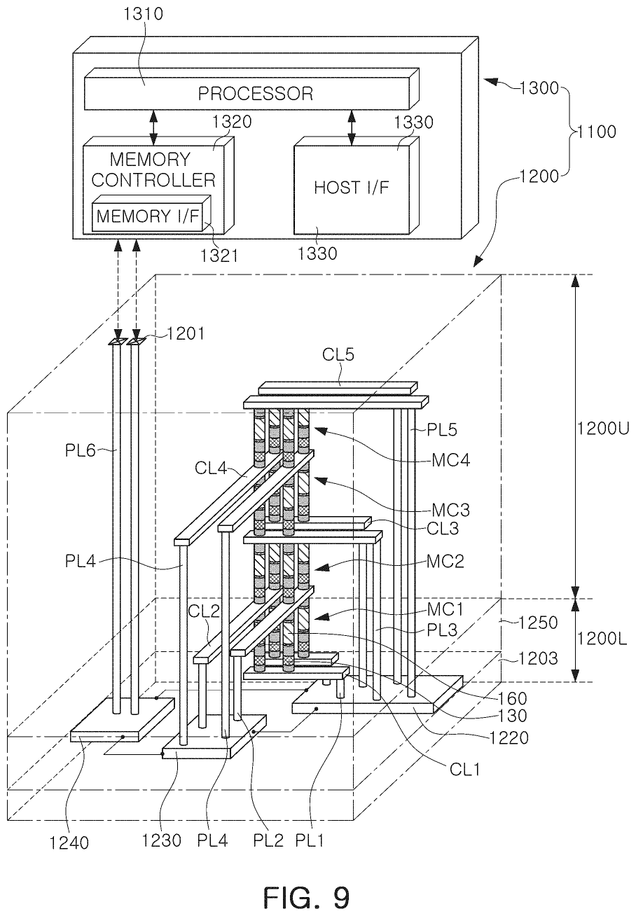

FIG. 9 is a schematic view of an electronic system including a semiconductor device according to an example embodiment.

Referring to FIG. 9, an electronic system 1100 according to an example embodiment may include a semiconductor device 1200 and a controller 1300 electrically connected to the semiconductor device 1200. The electronic system 1100 may be a storage device including the semiconductor device 1200 or an electronic device including a storage device. For example, the electronic system 1100 may be a solid state drive device (SSD) device including the semiconductor device 1200, a universal serial bus (USB) device, a computing system, a medical device, or a communications device.

The semiconductor device 1200 may be a semiconductor device according to one of the example embodiments described with reference to FIGS. 1 to 7. The semiconductor device 1200 may include a first structure 1200L and a second structure 1200U on the first structure 1200L.

The first structure 1200L may include a row driver 1220, a column driver 1230, a control logic 1240 electrically connected to the row driver 1220 and the column driver 1230. The row driver 1220 may include an address decoder circuit for selecting data storage material patterns (for example, 160 in FIG. 1) of a memory cell structure (for example, MCA in FIG. 1) to write data or to read data, and the column driver 1230 may include a read/write circuit to write data to the data storage material patterns (for example, 160 in FIG. 1) of the memory cell structure (for example, MCA in FIG. 1) or to read data from the data storage material patterns 160. Operations of the row driver 1220 and the column driver 1230 may be controlled by the control logic 1240. The first structure 1200L may be the lower structure (10 in FIG. 3) described with reference to FIGS. 1 to 3.

The second structure 1200U may include a plurality of memory cell structures stacked in a vertical direction.

As an example, the plurality of memory cell structures may include two or more memory cell structures. For example, the plurality of memory cell structures may include first to fourth memory cell structures MC1, MC2, MC3, and MC4 stacked in the vertical direction. Each of the first to fourth memory cell structures MC1, MC2, MC3, and MC4 may include the data storage material pattern 160 and the selector material pattern 130, as illustrated in FIG. 1. As another example, each of the first to fourth memory cell structures MC1, MC2, MC3, and MC4 may include various data storage material patterns and selector material patterns described with reference to FIGS. 2 to 7.

According to an example embodiment, a structure may include more than four memory cell structures vertically stacked.

The second structure 1200U may include first conductive lines CL1 disposed between the first memory cell structure MC1 and the first structure 1200L and extending in a first horizontal direction, second conductive lines CL2 extending in a second horizontal direction between the first memory cell structure MC1 and the second memory cell structure MC2, third conductive lines CL3 extending in the first horizontal direction between the second memory cell structure MC2 and the third memory cell structure MC3, fourth conductive lines CL2 extending in the second horizontal direction between the third memory cell structure MC3 and the fourth memory cell structure MC4, and fifth conductive lines CL5 extending in the first horizontal direction on the fourth memory cell structure MC4.

As an example, the first, third, and fifth conductive lines CL1, CL3, and CL5 may be wordlines, and the second and fourth conductive lines CL2 and CL4 may be bitlines.

The second structure 1200U may further include first, third, and fifth contact structures PL1, PL3, and PL5, electrically connecting the first, third, and fifth conductive lines CL1, CL, and CL5 to the row decoder 1200, and second and fourth contact structures PL2 and PL4 electrically connecting the second and fourth conductive lines CL2 and CL4 to the column driver 1230.

The second structure 1200 may include an input/output (I/O) pad 1201. The semiconductor device 1200 may further include an input/output (I/O) contact structure PL6 electrically connected to the I/O pad 1201 and extending inwardly of the first structure 1200L through the second structure 1200U to be electrically connected to a control logic 1240.

The electronic system 1100 may communicate with the controller 1300 through the I/O pad 1201 electrically connected to the control logic 1240. The controller 1300 may include a processor 1310, a memory controller 1322, and a host interface 1330. According to example embodiments, the electronic system 1100 may include a plurality of semiconductor devices 1200. In this case, the controller 1300 may control the plurality of semiconductor devices 1200.

The processor 1310 may control overall operations of the electronic system 1100 including the controller 1300. The processor 1310 may operate according to desired and/or alternatively predetermined firmware, and may control the memory controller 1320 to access the semiconductor device 1200. The memory controller 1320 may include a memory interface 1321 processing communications with the semiconductor device 1200.

A control command for controlling the semiconductor device 1200, data to be written to the data storage material patterns 160 of the memory cell structures MC1, MC2, MC3, and MC4 of the semiconductor device 1200, data to be read from the data storage material patterns 42 of the memory cell structures MC1, MC2, MC3, and MC4 of the semiconductor device 1200, and the like, may be transmitted through the memory interface 1321. The host interface 1330 may provide a communications function between the electronic system 1100 and an external host. When the control command is received from the external host through the host interface 1330, the processor 1310 may control the semiconductor device 1200 in response to the control command.

As described above, a composition of a threshold switching material and the content of a metal element may be adjusted, and thus, a semiconductor device having improved electrical characteristics and reliability may be provided.

One or more of the elements of the controller 1300 in FIG. 9 may include or be implemented in processing circuitry such as hardware including logic circuits; a hardware/software combination such as a processor executing software; or a combination thereof. For example, the processing circuitry more specifically may include, but is not limited to, a central processing unit (CPU) , an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments have been shown and described above, it will be apparent to those skilled in the art that modifications and variations could be made without departing from the scope of inventive concepts as defined by the appended claims.

What is claimed is:

1. A semiconductor device comprising:
a semiconductor substrate;
a circuit element on the semiconductor substrate;
a lower insulating structure covering the circuit element;
circuit interconnections in the lower insulating structure, the circuit interconnections being on the semiconductor substrate and electrically connected to the circuit element; and
an upper structure on the lower insulating structure,
the upper structure including first conductive lines, second conductive lines, and a memory cell structure between the first conductive lines and the second conductive lines,
the first conductive lines extending in a first horizontal direction,
the second conductive lines extending in a second horizontal direction, perpendicular to the first horizontal direction,
the memory cell structure including at least three electrode patterns, a data storage material pattern, and a selector material pattern overlapping each other in a vertical direction,
the selector material pattern includes a threshold switching material and a metal material,
the threshold switching material including germanium (Ge), arsenic (As), and selenium (Se),
the metal material including at least one of tungsten (W), titanium (Ti), aluminum (Al), and copper (Cu), and
a content of the metal material in the selector material pattern being greater than 0 atomic % and less than about 2 atomic %.

2. The semiconductor device of claim 1, wherein the threshold switching material is a Ge_{α}As_{β}Se_{γ}Te_{δ}Si_{η} material, where
α is in a range of about 13 atomic % to about 23 atomic %,
β is in a range of about 25 atomic % to about 35 atomic %,
γ is in a range of about 38 atomic % to about 50 atomic %,
δ is in a range of about 0.1 atomic % to about 6 atomic %, and
η is in a range of about 0.1 atomic % to about 8 atomic %.

3. The semiconductor device of claim 1, wherein the threshold switching material is a Ge_{α}As_{β}Se_{γ}In_{η} material, where
α is in a range of about 13 atomic % to about 23 atomic %,
β is in a range of about 25 atomic % to about 35 atomic %,
γ is in a range of about 38 atomic % to about 50 atomic %, and
η is in a range of about 0.1 atomic % to about 6 atomic %.

4. The semiconductor device of claim 1, wherein the threshold switching material is a Ge_{α}As_{β}Se_{γ}Si_{η}In_{δ} material, where
α is in a range of about 13 atomic % to about 23 atomic %,
β is in a range of about 25 atomic % to about 35 atomic %,
γ is in a range of about 38 atomic % to about 50 atomic %,
η is in a range of about 0.1 atomic % to about 8 atomic %, and
δ is in a range of about 0.1 atomic % to about 6 atomic %.

5. The semiconductor device of claim 1, wherein the threshold switching material is a Ge_{α}As_{β}Se_{γ}Ga_{η} material, where
α is in a range of about 13 atomic % to about 23 atomic %,
β is in a range of about 25 atomic % to about 35 atomic %,
γ is in a range of about 38 atomic % to about 50 atomic %, and
η is in a range of about 0.1 atomic % to about 6 atomic %.

6. The semiconductor device of claim 1, wherein the threshold switching material is a Ge_{α}As_{β}Se_{γ}Ga_{η}In_{δ} material, where
α is in a range of about 13 atomic % to about 23 atomic %,
β is in a range of about 25 atomic % to about 35 atomic %,
γ is in a range of about 38 atomic % to about 50 atomic %,
η is in a range of about 0.1 atomic % to about 6 atomic %, and
δ is in a range of about 0.1 atomic % to about 6 atomic %.

7. The semiconductor device of claim 1, wherein an amount of variation of a threshold voltage of the selector material pattern is about 35 mV/dec or less.

8. The semiconductor device of claim 1, wherein a volatilization temperature of the selector material pattern is about 250° C. or more.

9. The semiconductor device of claim 1, wherein a vitrification temperature of the selector material pattern is about 350° C. or more.

10. The semiconductor device of claim 1, wherein the selector material pattern further includes at least one of boron (B), carbon (C), nitrogen (N), and oxygen (O).

11. The semiconductor device of claim 1, further comprising:
third conductive lines, wherein
the data storage pattern is a first data storage material pattern,
the selector material pattern is a first selector material pattern
the memory cell structure is a first memory cell structure including the first data storage material pattern and the first selector material pattern, and
the upper structure further includes a second memory cell structure on the second conductive lines,
the second memory cell structure overlaps the first memory cell structure in the vertical direction,
the second memory cell structure includes a second data storage material pattern and a second selector material pattern,
the third conductive lines extend in the first horizontal direction, and
the third conductive lines are above the second memory cell structure.

12. The semiconductor device of claim 1, wherein a thickness of the data storage material pattern is about two to about four times greater than a thickness of the selector material pattern.

13. A semiconductor device comprising:
a semiconductor substrate;
first conductive lines extending in a first horizontal direction on the semiconductor substrate;
second conductive lines extending in a second horizontal direction perpendicular to the first horizontal direction;
a memory cell structure on the first conductive lines and disposed such that the second conductive lines are on the memory cell structure,
the memory cell structure including a first electrode pattern on the first conductive lines, a second electrode pattern on the first electrode pattern, and a data storage material pattern and a selector material pattern between the first electrode pattern and the second electrode pattern,
the selector material pattern including a threshold switching material including germanium (Ge), arsenic (As), and selenium (Se),
the selector material pattern including a metal material in common with the first conductive lines or the second conductive lines, and
the metal material of the selector material pattern being in a region adjacent to side surfaces of the selector material pattern.

14. The semiconductor device of claim 13, wherein the threshold switching material is a Ge_{α}As_{β}Se_{γ}Te_{δ}Si_{η} material, where
α is in a range of about 13 atomic % to about 23 atomic %,
β is in a range of about 25 atomic % to about 35 atomic %,
γ is in a range of about 38 atomic % to about 50 atomic %,
δ is in a range of about 0.1 atomic % to about 6 atomic %, and
η is in a range of about 0.1 atomic % to about 8 atomic %.

15. The semiconductor device of claim 14, wherein
the metal material is tungsten (W), and
a content of the metal material included in the selector material pattern is greater than 0 atomic % and less than about 2 atomic %.

16. The semiconductor device of claim 13, wherein the threshold switching material is a Ge_{α}As_{β}Se_{γ}In_{η} material, where
α is in a range of about 13 atomic % to about 23 atomic %,
β is in a range of about 25 atomic % to about 35 atomic %,
γ is in a range of about 38 atomic % to about 50 atomic %, and
η is in a range of about 0.1 atomic % to about 6 atomic %.

17. The semiconductor device of claim 16, wherein the metal material is tungsten (W), and
wherein a content of the metal material included in the selector material pattern is greater than 0 atomic % and less than about 2 atomic %.

18. A semiconductor device comprising:
a semiconductor substrate;
first conductive lines extending in a first horizontal direction on the semiconductor substrate;
second conductive lines on the first conductive lines and extending in a second horizontal direction perpendicular to the first horizontal direction; and
a memory cell structure between the first conductive lines and the second conductive lines,
the memory cell structure including a first electrode pattern on the first conductive lines, a second electrode pattern on the first electrode pattern, and a data storage material pattern and a selector material pattern between the first electrode pattern and the second electrode pattern,
the selector material pattern including a first material, a second material, and a third material,
the first material including at least one of germanium (Ge), arsenic (As), and selenium (Se),
the second material including at least one of tellurium (Te), silicon (Si), indium (In), and gallium (Ga), and
the third material including at least one of tungsten (W), titanium (Ti), aluminum (Al), and copper (Cu), and
a content of the first material and a content of the second material each being greater than a content of the third material.

19. The semiconductor device of claim 18, wherein the content of the first material is greater than the content of the second material.

20. The semiconductor device of claim 19, wherein
the content of the third material is greater than 0 atomic % of a total content of the first material, the second material, and the third material, and
the content of the third material is less than about 2 atomic % of the total content of the first material, the second material, and the third material.
